(19) United States
(12) Patent Application Publication
(10) Pub. No.: US 2010/0322784 A1
(43) Pub. Date: Dec. 23, 2010

(54) SOLAR WATER HEATING SYSTEM

(75) Inventors: Michael R. Rubio, Chico, CA (US); Carthel D. Boring, Oroville, CA (US); William E. Happersett, JR., Walnut Creek, CA (US); Nathan A. Aronson, Chico, CA (US); Shayne B. Turner, Magalia, CA (US); David C. Masse, Oroville, CA (US); Andrew J. Bacigalupo, Chico, CA (US); Brian H. Smith, Chico, CA (US); Joann C. Greene, Chico, CA (US)

Correspondence Address: Beyer Law Group LLP, P.O. BOX 1687, Cupertino, CA, 95015-1687, US

(73) Assignee: FAFCO, INC., Chico, CA (US)

(21) Appl. No.: 12/816,983

(22) Filed: Jun. 16, 2010

Related U.S. Application Data
(60) Provisional application No. 61/218,861, filed on Jun. 19, 2009.

(51) Int. Cl. F04B 39/00; F24J 2/04; F24J 2/30; F24J 2/46; H01L 31/042; B01D 35/22

(52) U.S. Cl. 417/53; 126/640; 126/643; 126/623; 136/244; 210/181

(57) ABSTRACT

A variety of arrangements and methods relating to a solar water heating system are described. Various implementations involve a relatively lightweight, affordable, low-pressure solar water heating system that is easier to ship and assemble and that is resistant to overheating and freezing damage. In one aspect of the invention, a solar water heating system includes a solar collector panel, a piping system and an improved, self-regulating expansion reservoir. Some designs involve automatic filtration, push fittings, a method for regulating power from a photovoltaic panel, UV resistant polymer components and/or other features. In a particular embodiment of the invention, multiple pumps, a heat exchanger and a controller for a solar water heating system are integrated into a single, compact module.

### CROSS-REFERENCE TO RELATED APPLICATIONS

This application claims priority benefit of U.S. Provisional Patent Application Nos. 61/218,861, filed Jun. 19, 2009, which is incorporated herein by reference in its entirety for all purposes.

### FIELD OF THE INVENTION

The present invention relates generally to improvements in solar water heating systems. One aspect of the present invention relates to a solar water heating system with a self-regulating expansion reservoir. In another aspect, a solar water heating system with an improved filtering mechanism is described. An additional aspect involves a method for detecting problems in the operation of the solar water heating system and/or for regulating input voltage from an associated photovoltaic panel. Various embodiments of the present invention involve push fittings on a header of a solar collector panel and the ability to draw power from both a photovoltaic panel and the electrical grid.

### BACKGROUND OF THE INVENTION

Solar heater systems are designed to capture heat from the sun and to store the solar heat until the heat is needed. In solar water heaters, the heat is ultimately transferred to water. Solar water heaters, which typically include a collector and storage tank, come in various forms including active, passive, direct and indirect systems.

In active, direct systems, the collector is typically a flat plate collector, which includes a rectangle box, tubes that extend through the box and a transparent cover that covers the box. The tubes help capture heat and transfer the heat to water inside the tubes. A pump is used to circulate water from a storage tank through the collector and back to the storage tank (typically located in the house). The pump pumps the hot water from the collector into the tank and the colder water out of the tank and into the collector. The pump is typically controlled by a control system that activates the pump when the temperature in the collector is higher than the temperature in the storage tank. The control system may also deactivate the pump when the temperature in the collector is lower than the temperature in the storage tank. In some cases, the storage tank may double as a hot water heater in order to back up the solar heating, i.e., it can heat the water when the temperature of the water in the collector is low. One advantage of active systems is that they provide better control of the system and therefore they can be operated more efficiently than other systems. Furthermore, using the control system, active systems can be configured to protect the collector from freezing in colder climates.

In passive systems, the heated water is moved via natural convection or city water pressure rather than using pumps. Although passive systems are generally less efficient than active systems, the passive approach is simple and economical. Compared to active systems, the passive system does not require controls, pumps, sensors or other mechanical components and therefore it is less expensive to operate and further it requires little or no maintenance over its lifetime. Passive systems come in various forms including batch and thermosiphon systems.

Batch systems such as breadbox solar water heaters or integrated collector storage systems are thought of as the simplest of all conventional solar water heaters. In batch systems, the storage tank is built into or integrated with the collector, i.e., a self-contained system that serves as a solar collector and a storage tank. Batch systems typically consist of one or more storage tanks, which are disposed in an insulated enclosure having a transparent cover on one side. The side of the storage tanks facing the transparent cover is generally colored black to better absorb solar energy. Batch systems use water pressure from the city source (or well) to move water through the system. Each time a hot water tap is opened, heated water from the storage tank is delivered directly to the point of use or indirectly through an auxiliary tank (e.g., hot water heater). One advantage of batch systems is that the water does not have to be stored separately from the collector. Furthermore, due to the large mass storage, batch systems typically do not encounter freezing problems in colder climates.

Thermosiphon systems, on the other hand, include a flat plate collector and a separate storage tank. The flat plate collector may be similar to the flat plate collector used in the active system. However, unlike the active system, the storage tank is mounted above the collector to provide natural gravity flow of water, i.e., the heated water rises through the collector to the highest point in the system (e.g., top of storage tank) and the heavier cold water in the storage tank sinks to the lowest point in the system (e.g., bottom of collector) thereby displacing the lighter heated water. Most literature on the subject discusses placing the storage tank at least 18 inches above the collector in order to prevent reverse thermosiphoning at night when the temperatures are cooler.

The above descriptions generally refer to direct systems, where potable water is circulated directly from a storage tank through a collector. Another category of solar water heating systems is an indirect system. In an indirect system, two separate fluid loops are maintained. A first fluid loop, which is filled with a heat transfer fluid, circulates through the solar collector. A second fluid loop, which is filled with potable water, circulates through the storage tank. The two fluid loops meet at a heat exchanger, where heat collected by the first fluid loop is transferred to the second fluid loop. In some implementations, there is anti-freeze (e.g., glycol) in the heat transfer fluid. In other implementations, the heat transfer fluid is periodically transferred out of the collector and stored in a drainback tank. Such approaches can help prevent the heat transfer fluid from freezing.

Unfortunately, conventional solar water systems suffer from several drawbacks. For one, most systems are bulky devices formed from large, awkward and heavy parts and therefore they are difficult to manage and install. This is especially true on roofs and for do it yourselfers with limited support. In some cases, due to the weight of the system, the roof underneath the system must be made more structurally sound. Furthermore, because these systems are large and heavy, the costs of shipping these products are exorbitantly high. In fact, in some cases, the cost of shipping may be higher than the cost of the product itself. Another drawback with these systems is that they tend not to be aesthetically pleasing.

While existing arrangements and methods for solar water heating work well, there are continuing efforts to further improve the reliability, affordability and performance of solar water heating systems.

### SUMMARY OF THE INVENTION

The present invention relates to an improved solar water heating system. Various implementations involve a low-pressure, lightweight expansion reservoir, a system for routing power from a photovoltaic panel and/or the electrical grid, an improved filtering mechanism, a header insert assembly and other features.

In one aspect of the present invention, a solar water heating system is described. The solar water heating system includes a solar collector panel, a piping system and an expansion reservoir. The expansion reservoir includes a fluid passage, a deformable bladder and a housing that encases the fluid passage and the deformable bladder. The fluid passage of the expansion reservoir is coupled with the solar collector panel and another suitable component in the solar water heating system (e.g., a heat exchanger). The deformable bladder is disposed adjacent to the fluid passage and includes at least one aperture. The deformable bladder is arranged to self-regulate its internal pressure and volume. That is, air is expelled out of the aperture from the deformable bladder when pressure in the fluid passage increases. Air is drawn into the deformable bladder through the aperture when the contraction of fluid in the fluid passage forms a vacuum in the expansion reservoir.

The fluid passage of the expansion reservoir may include a pressure release valve. The pressure release valve releases vapor from the fluid passage of the expansion reservoir when the internal pressure of the fluid passage reaches a predetermined pressure level. Some implementations involve a predetermined pressure level that is below approximately 10 psi. In some embodiments, the housing and/or other components of the expansion reservoir are made from a UV-resistant polymer. As a result, the expansion reservoir can be substantially lighter than a traditional expansion tank and may be more easily installed on the rooftop of a building or residence.

The solar water heating system may include a wide variety of features, depending on the needs of a particular application. By way of example, it may include a controller and one or more pumps that can be powered by either a photovoltaic panel or the electrical grid. The solar collector panel may include headers with push fittings. The end of the header may be fitted with a header insert assembly that helps form a secure, watertight connection between a pipe and the header. In various embodiments, the pipe may be secured to the header without the use of tools or welding.

In another aspect of the present invention, a system for back flushing a filter in a solar water heating system is described. A water storage tank, an external water source (e.g., a water main) and another component of a solar water heating system (e.g., a heat exchanger) are fluidly coupled via a piping system. A pipe adapter with three openings is positioned within the piping system. The first, second and third openings of the pipe adapter are fluidly coupled with the water storage tank, the solar water heating component and the water source, respectively. The first, second and third openings of the pipe adapter provide access to first, second and third fluid conduit passages within the pipe adapter, which intersect at an intersection point. A filter is positioned at the intersection point. The filter is arranged to filter and trap debris from the water storage tank when water is passed from the water storage tank to the solar water heating component. Additionally, when water is passed from the water source to the water storage tank, the water cleans away the debris from the filter and carries it back into the water storage tank.

In another aspect of the present invention, a method of regulating electrical power in a solar water heating system is described. An input voltage is received from a photovoltaic panel. The photovoltaic panel is coupled with an interface module, which includes one or more pumps and a heat exchanger. The interface module is also fluidly coupled with a water storage tank and a solar collector panel via a piping system. A determination is made as to whether the received input voltage exceeds a predetermined level. If such a determination is made, the input voltage from the photovoltaic panel is routed to the pump to activate the pump. If the input voltage is too low, the pump may not be activated. Alternatively, in some embodiments, the pump may be activated using grid power, if access to the electrical grid is available.

Some designs may involve a wide variety of additional operations. For example, while the pump is activated, another input voltage may be received from the photovoltaic panel. A determination is made as to whether the second input voltage is below a predetermined level. When such a determination is made, the activated pump is shut off. After the shutting off of the pump, a timer may be initiated. An input voltage may again be received from the photovoltaic panel. When the timer exceeds a predetermined period of time (e.g., 2-3 minutes) and the input voltage exceeds a predetermined level (e.g., 13-15VDC), the shut off pump may be reactivated. If the appropriate amount of time has not passed, the pump may not be turned on again, even if the required input voltage level has been reached. This approach can reduce wear and tear on the pumps by preventing them from being started and stopped in rapid succession.

The method may also involve operations for detecting a problem in the solar water heating system and alerting a user of the problem. Initially, a temperature difference is calculated between two temperature readings. The first temperature is based on a roof sensor that is positioned near the solar collector panel. The second temperature is based on a sensor in the water storage tank. A determination is made as to whether the temperature difference exceeds a predetermined level for a predetermined period of time (e.g., 30° F. for 4 hours.) After such a determination is made, an error message is displayed on a display screen. As a result, a user of the solar water heating system can be alerted of the issue, so that appropriate repairs can take place.

### BRIEF DESCRIPTION OF THE DRAWINGS

The invention and the advantages thereof, may best be understood by reference to the following description taken in conjunction with the accompanying drawings in which:

FIG. 1 illustrates a solar water heating system according to a particular embodiment of the present invention.

FIGS. 2A-2B illustrate an expansion reservoir according to a particular embodiment of the present invention.

FIGS. 3A-3B illustrate a pipe adapter and a filter according to a particular embodiment of the present invention.

FIG. 4A is a block diagram illustrating a controller, a pump, a water storage tank and sensors according to a particular embodiment of the present invention.

FIG. 4B is a flow diagram illustrating a method of determining whether a solar water heating system is operating properly according to a particular embodiment of the present invention.

FIG. 4C is a block diagram illustrating a controller, pumps and a photovoltaic panel according to a particular embodiment of the present invention.

FIG. 4D is a circuit diagram for a controller that is used in a solar water heating system according to a particular embodiment of the present invention.

FIG. 4E is a flow diagram relating to a method for regulating input voltage from a photovoltaic panel according to a particular embodiment of the present invention.

FIGS. 5A-5C illustrates a header insert assembly according to a particular embodiment of the present invention.

FIG. 6A illustrates an interface module according to a particular embodiment of the present invention.

FIG. 6B is a perspective view of a hydroblock according to a particular embodiment of the present invention.

FIG. 7 illustrates an interface module with an integrated heat sink, pumps, controller and display according to another embodiment of the present invention.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

Conventional, indirect solar water heating systems typically use glazed, metallic solar collector panels. That is, the solar collector panel is encased in a transparent material, such as polycarbonate or glass. Glazed collector panels create a “greenhouse effect” around the panel and help maximize heat retention. They are particularly useful in colder climates, where it is desirable to draw as much heat as possible out of limited sunlight. Additionally, the more thermal energy the collector can absorb, the higher the maximum temperature of the heated potable water. Presumably due in part to these advantages, glycol-based, indirect solar water heating systems certified for sale in the United States generally use glazed collector panels.

The heat transfer fluid within such systems can reach very high temperatures and pressures. To withstand such temperatures and pressures, the collector, piping and/or other parts of the system are typically made of metal. Although resilient, the use of a metal collector and piping add substantially to the overall bulk and weight of the solar water heating system. This makes the system expensive to ship and difficult for a homeowner to install on his or her rooftop. Additionally, the high temperatures and pressures can increase wear and tear on the system and can result in overheating problems.

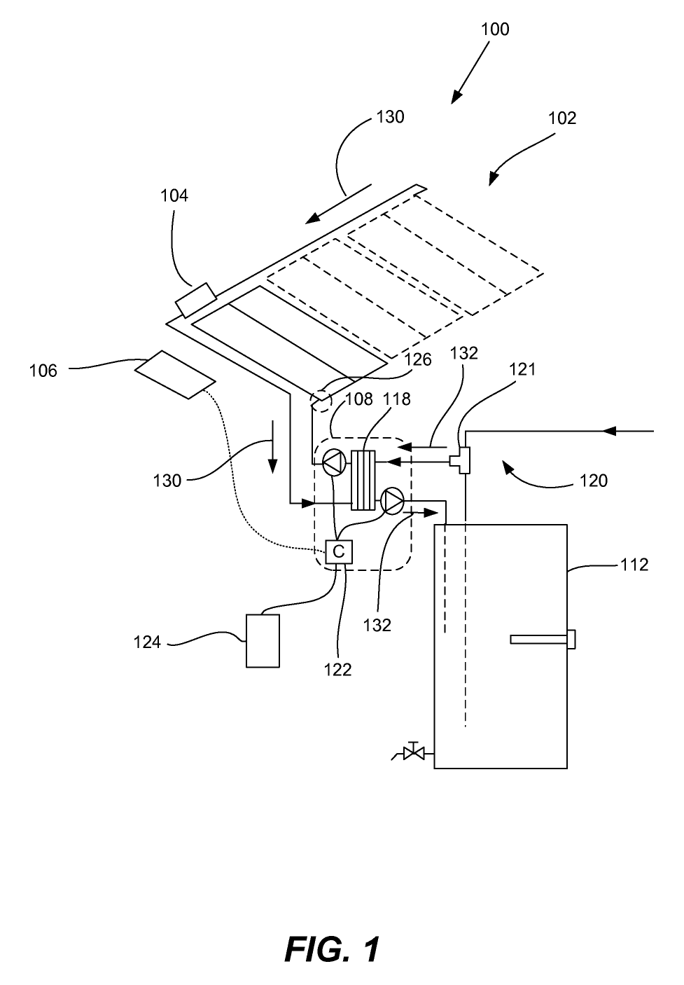

Various aspects of the present invention address one or more of the above concerns. FIG. 1 illustrates an indirect solar water heating system 100 according to one embodiment of the present invention. The solar water heating system 100 includes one or more polymer solar collector panels 102, a roof-mounted, low-pressure expansion reservoir 104, a photovoltaic panel 106, a pipe adapter 121 with an improved filtering mechanism, a water storage tank 112 and an interface module 108 that includes a heat exchanger 118 and a controller 122. In the illustrated embodiment, an indirect system is shown, where the heat exchanger 118 transfers thermal energy from a first fluid loop 130 (i.e., the loop that circulates between the solar collector panel 102 and the interface module 108) to a second fluid loop 132 (i.e., the loop that circulates between the water storage tank 112 and the interface module 108.) It should be appreciated that various components of the solar water heating system 100 can be implemented in direct systems as well.

The solar water heating system 100 offers several advantages over conventional systems. More specifically, the solar collector panel 102 is unglazed and formed at least partially from a relatively lightweight polymer material. As a result, it is generally more portable, affordable and easier to install then its metallic, glazed counterparts. The use of an unglazed, polymer solar collector panel 102 also causes the heat transfer fluid in the panel to reach relatively lower maximum temperatures and pressures. This feature provides protection against overheating and eliminates the need to form the piping system and collector largely of metal. The use of various polymer materials in a solar water heating system is described in other applications filed by the assignee of the present invention, including U.S. application Ser. No. 11/731,033, entitled “Kit for Solar Water Heating System,” filed Mar. 29, 2007, and U.S. Provisional Application No. 60/787,448, entitled “Polymer Based Domestic Solar Water Heater,” filed Mar. 29, 2006, which are hereby incorporated by reference in their entirety for all purposes.

Several other useful and novel features are presented in the solar water heating system 100. In the illustrated embodiment, for example, expansion reservoir 104 is arranged to help reduce the buildup of pressure in the piping system 120 while minimizing losses through evaporation. In contrast to traditional metal expansion tanks, various embodiments of the expansion reservoir 104 involve lower pressures and can be made substantially of a lightweight polymer material rather than metal.

Another feature of the solar water heating system 100 is the pipe adapter 121, which includes an internal filter. The positioning of the pipe adapter 121 in the piping system 120 allows the filter to catch debris from the water storage tank 112 as potable water is circulated between the water storage tank 112 and the heat exchanger 118. The filter is automatically and conveniently cleaned of debris when water is pulled in from an external water source (e.g., a water main) to refill the water storage tank 112.

Additional noteworthy features of the solar water heating system 100 are the photovoltaic panel 106, push fittings 126 and interface module 108, which includes a controller 122 and pumps 110. In the illustrated embodiment, the pumps 100 can be powered by either the photovoltaic panel 106 or the electrical grid through the power supply 124 (e.g., an AC/12VDC power supply.) Additionally, interface module 108 and controller 122 are designed to regulate input voltage from the photovoltaic panel 106 and help identify errors in the operation of the solar water heating system. The push fittings 126 allow the piping system 120, solar collector panel 102 and/or other components of the system to be connected without or with minimal use of welding or tools. The aforementioned features as well as other features will be described in greater detail in the specification below.

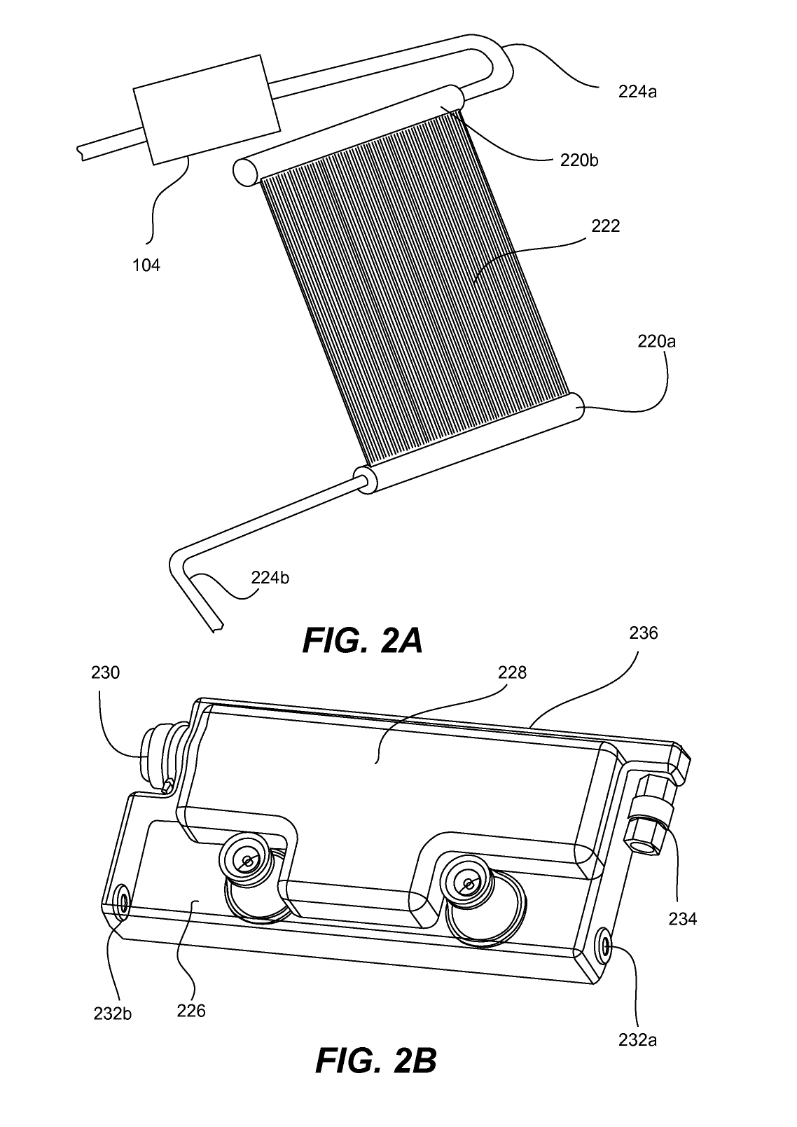

Referring now to FIGS. 2A and 2B, a solar collector panel 102 and an expansion reservoir 104 according to one embodiment of the present invention will be described. The solar collector panel 102 includes an absorber 222 that extends between a top header 220b and a bottom header 220a. In the illustrated embodiment, a heat transfer fluid from the interface module 108 of FIG. 1 is passed through lower pipe 224b, bottom header 220a, absorber 222 and upper header 220b. As the heat transfer fluid passes through the solar collector panel 102, it is heated by incoming solar radiation. The heated heat transfer fluid then passes through upper pipe 224a and enters the expansion reservoir 104. After leaving the expansion reservoir 104, the heat transfer fluid is recirculated back to the interface module 108.

FIG. 2B illustrates an enlarged perspective view of the expansion reservoir 104 of FIG. 2A according to a particular embodiment of the present invention. The expansion reservoir 104 includes a fluid passage 226, a deformable bladder 228 and a pressure release valve 234. The fluid passage 226 and the deformable bladder 228 are adjacent to one another and are encased in a housing 236. In the illustrated embodiment, a heat transfer fluid flows into the fluid passage 226 through inlet 232a and out of the fluid passage through outlet 232b. Air can be released from and drawn into the deformable bladder 228 through an aperture 230. The pressure release valve 234 is coupled to the fluid passage 226 and is arranged to release vapor therefrom.

As the temperature of the fluid in the fluid passage 226 increases, it expands and the pressure in the fluid passage 226 increases. The fluid passage 226 will then press flush against and deform the deformable bladder 228. The deformable bladder 228 gives room to the fluid to expand further and thus helps to relieve pressure within the fluid passage 226. As the fluid passage 226 fills and the pressure grows, the deformable bladder 228 will release air through the aperture 230 until it is entirely compressed or deflated. If the pressure within the fluid passage 226 continues to build, the pressure release valve 234 will release vapor when the pressure within the fluid passage 226 reaches a predetermined maximum pressure level. A predetermined maximum pressure level of less than approximately 10 psi works well in various implementations. In some embodiments, the predetermined maximum pressure level is between 0.5 and 2 psi.

The idea of using an expansion tank with a deformable diaphragm to relieve pressure within a solar water heating system is known in the art. However, the expansion tank 104 of FIG. 2B differs from a conventional expansion tank in several ways. For one, a conventional expansion tank typically maintains a relatively high internal pressure level. A pressure level of between 20 and 30 psi is common. As noted above, the expansion tank 104 is arranged to accommodate a much lower internal pressure.

One reason for such high pressure levels in a conventional expansion tank is that a conventional expansion tank is generally positioned low in a solar water heating system e.g., at the level of the pumps and water storage tank and substantially below the solar collector. In that position, the conventional expansion tank must apply a steady amount of pressure to help prevent cavitation from damaging the pumps. By contrast, in some embodiments of the present invention, the expansion tank 104 is positioned near or at the highest point in the system e.g., near or adjacent to the solar collector panel on the rooftop of a building. In that position, the expansion tank 104 does not need to preserve a high internal pressure. That is, the column of water below the expansion tank 104 in the system can apply sufficient pressure to the pumps to help prevent cavitation.

The differences in internal pressure between a conventional expansion tank and the expansion reservoir 104 can lead to other structural differences as well. In a conventional expansion tank, the deformable diaphragm deforms as pressure in the expansion tank increases. However, the deformable diaphragm is always at least partially inflated to help maintain a high pressure level, while by contrast the deformable bladder 228 of the expansion reservoir 104 can be almost or entirely deflated when the fluid passage is entirely filled. Unlike the deformable diaphragm of a traditional expansion tank, the deformable bladder 228 has an aperture 230 through which the deformable bladder 228 can release air to the ambient environment. The aperture 230 can designed in various ways. For example, it can take the form of one or more holes or valves. In the preferred embodiment, the aperture 230 is simply a small hole that is perpetually open, although in other embodiments it could also be selectively, intermittently and/or partially open. In still other embodiments, air is released through one or more holes that are distinct from those through which air is received.

The deformable bladder 228 automatically self-regulates its internal pressure and volume in response to the expansion and contraction of the fluid in the fluid passage 226. Generally, air flows in and out of the aperture 230 in the deformable bladder 228 to help maintain an equilibrium between the internal pressure of the deformable bladder 228 and the ambient pressure outside of the bladder 228. As noted earlier, the aperture 230 releases air from the deformable bladder 228 as the fluid in the fluid passage 226 becomes hotter, expands and presses against the bladder. The deformable bladder 228 thus shrinks. When the fluid in the fluid passage gets colder, the fluid contracts. This contraction can form a vacuum in the expansion reservoir 104. The vacuum then draws in air through the aperture 230 to fill the deformable bladder, which causes the volume of the deformable bladder 230 to increase. Depending on the design of the expansion reservoir 104, such features can play an important role in preventing a polymer expansion reservoir 104 from crumpling in on itself.

The expansion reservoir 104 and a conventional expansion tank may also differ in terms of composition. In a preferred embodiment, the housing 236 and/or other parts of the expansion reservoir 104 is made of a UV-resistant polymer. This is in contrast to a conventional expansion tank, which, as noted earlier, must tolerate much higher internal pressures and therefore is typically made of a metal. The use of metal, however, can significantly increase the weight and manufacturing costs of the tank and make it difficult to install. The polymer-based reservoir polymer 104 is relatively lightweight and therefore easier to install on a rooftop.

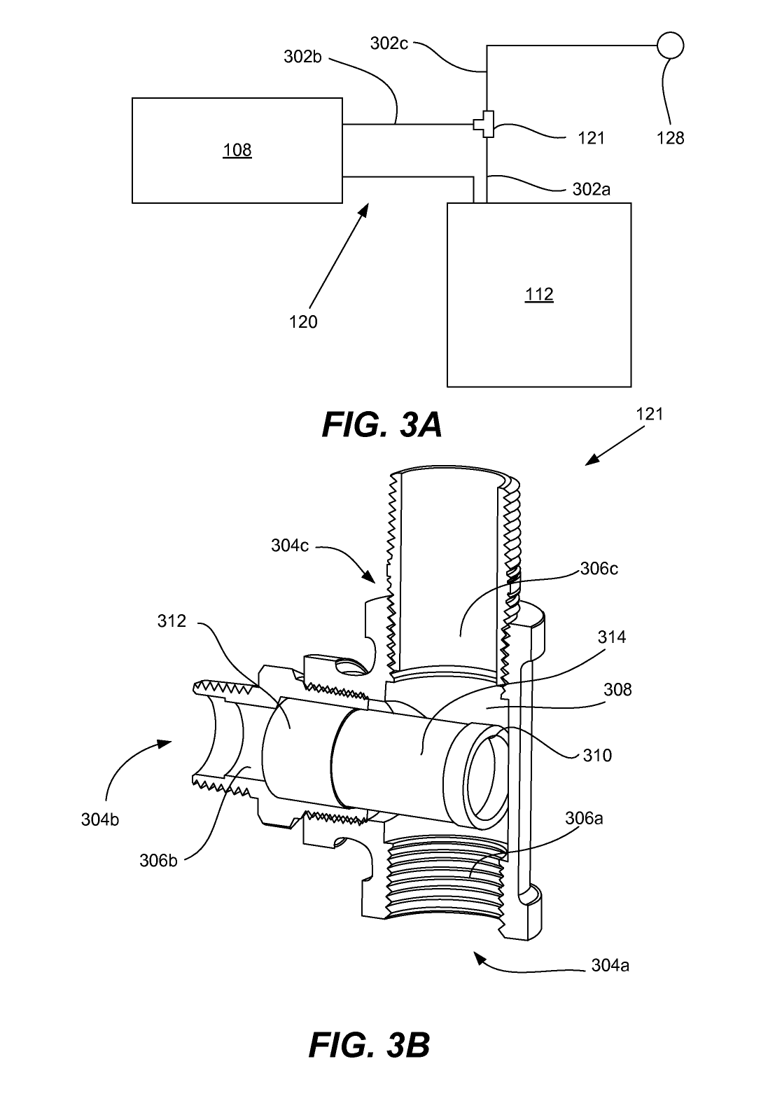

Referring now to FIG. 3A and FIG. 3B, an improved filtering mechanism for use in a solar water heating system according to one embodiment of the present invention will be described. FIG. 3A illustrates a pipe adapter 121, a solar water heating component 108, a water storage tank 112 and a water source 128 (e.g., a water main, etc.). In the illustrated embodiment, the solar water heating component 108 is an interface module with a heat exchanger, although in other embodiments solar water heating component 108 may be any suitable component in a solar water heating system. A piping system 120 fluidly couples the aforementioned components.

Generally, the pipe adapter 121 helps reduce clogging in a solar water heating system. More specifically, a filter in the pipe adapter 121 is designed to trap debris from the water storage tank 112. When water is drawn from an external water source 128 into the storage tank 112, the pipe adapter and the piping system is arranged so that the incoming water backflushes and cleans the filter. Therefore, in some residential applications, whenever a homeowner draws hot water from a faucet and drains the storage tank, the filter is automatically cleaned by the water that comes in from the local water main to refill the storage tank.

The operation and structure of the pipe adapter 121 will be described with reference to FIG. 3B, which illustrates an enlarged view of the pipe adapter 121. Pipe adapter 121 includes first, second and third openings 304a, 304b and 304c. The first, second and third openings lead to first, second and third fluid conduit passages 306a, 306b and 306c within the pipe adapter 121. The fluid conduit passages fluidly connect to one another at an intersection point 308. The filter 310 is arranged at the intersection point 308. In the illustrated embodiment, the pipe adapter 121 takes the form of a t-joint, although the number of arms and exact configuration of the pipe adapter may vary depending on the needs of a particular application.

Each opening of the pipe adapter 121 is fluidly coupled to a separate pipe. For example, in FIGS. 3A and 3B, the first opening 304a of the pipe adapter is connected to a pipe 302a that leads to the water storage tank 112. The second opening 304b is connected to a pipe 302b that leads to the solar water heating component 108. (In the illustrated embodiment, the solar water heating component 108 is an interface module with a heat exchanger. Pipe 302b is thus part of a fluid loop that circulates water between the storage tank and the heat exchanger.) Opening 304c of the pipe adapter 121 is connected to pipe 302c, which leads to the water source 128.

Referring now again to FIG. 3B, the filtering and backflushing processes according to one embodiment of the present invention will be described. Water is drawn from the water storage tank 112 to the interface module through the first opening 304a, the first fluid conduit passage 306a, the intersection point 308, the second fluid conduit passage 306b and the second opening 304b. The water carries debris from the storage tank 112, which is caught and trapped on the filter 310. In some embodiments, a pump at the interface module or the solar water heating component 108 pulls the water such that most of the water is directed down the second fluid conduit passage 306b rather than the third conduit passage 306c.

Afterward, water is drawn from the water source 128 to the water storage tank 112. This can happen, for example, when a homeowner draws hot water from the water storage tank and water is brought in from the water main to refill the tank. In this case, water passes through the third opening 304c, the third fluid conduit passage 306c, the intersection point 308, the first fluid conduit passage 306a and the first opening 304a of the pipe adapter 121. The water flows through the filter 121 and carries the debris deposited on the filter 310 back into the water storage tank 112.

The filter 310 is arranged to capture debris while allowing water to easily pass through. The filter 310 can be positioned in almost any location within the pipe adapter 121 and can have a wide variety of designs, shapes and sizes. In the illustrated embodiment, for example, the filter 310 is a hollow, cylindrical structure that includes a rubber end 312 and a wire mesh 314. The rubber end forms a watertight seal with the insides of the second fluid conduit passage 306b of the pipe adapter 121. The wire mesh 314, which is arranged to capture debris from the water storage tank 112, extends into the intersection point 308 of the pipe adapter 121 and is positioned between the first fluid conduit passage 306a and the third conduit passage 306c. In various embodiments, the filter 310 is positioned in the pipe adapter 121 so that the water flow that deposits debris on the filter and the water flow that cleans the debris off the filter travel in opposite directions, although this is not a requirement.

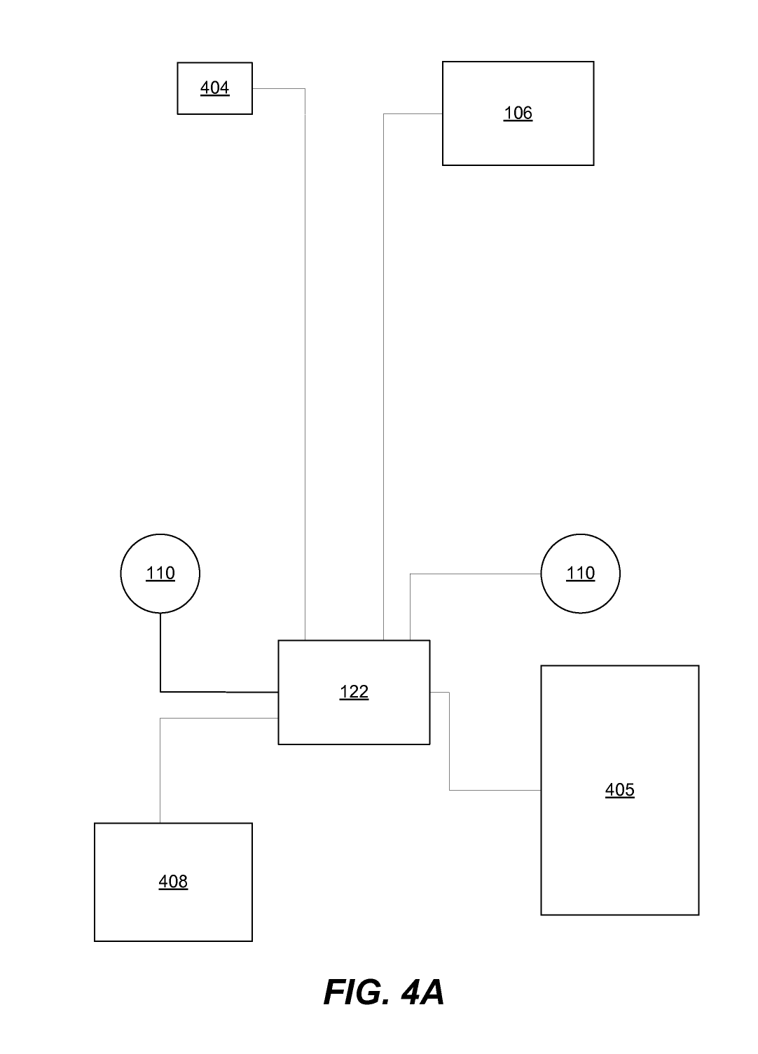

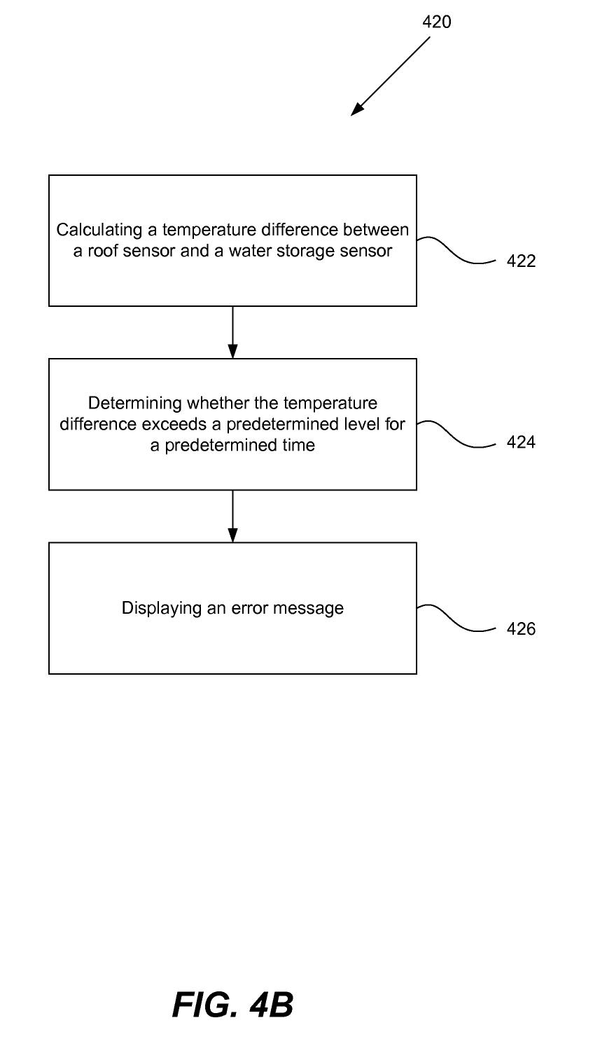

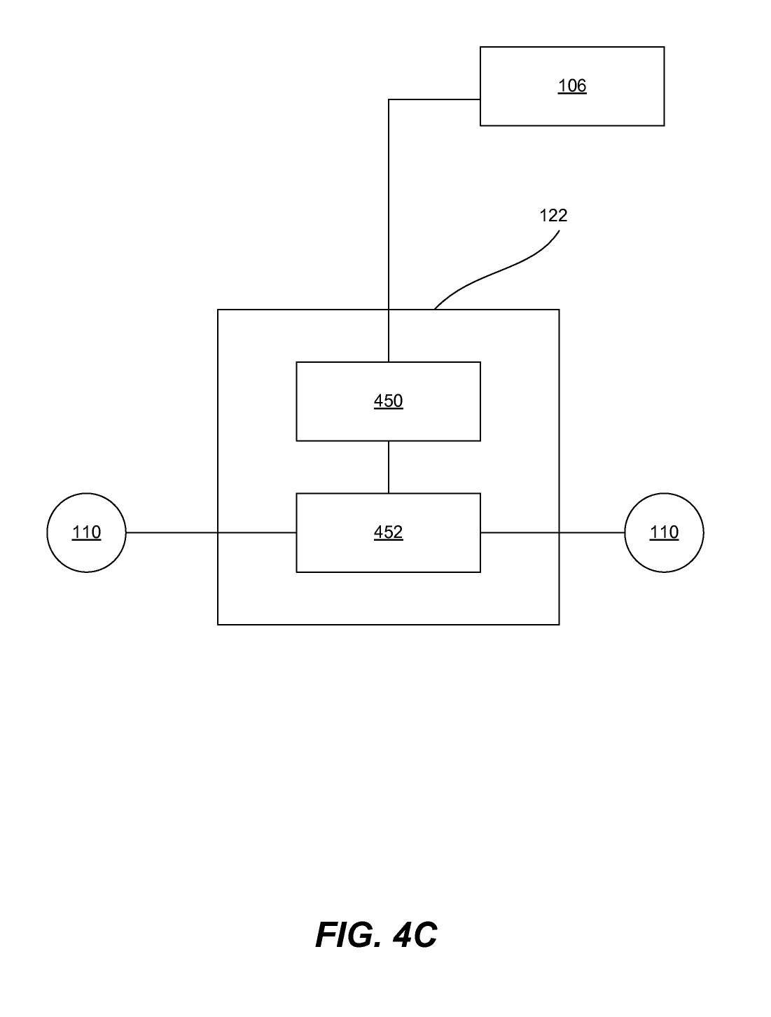

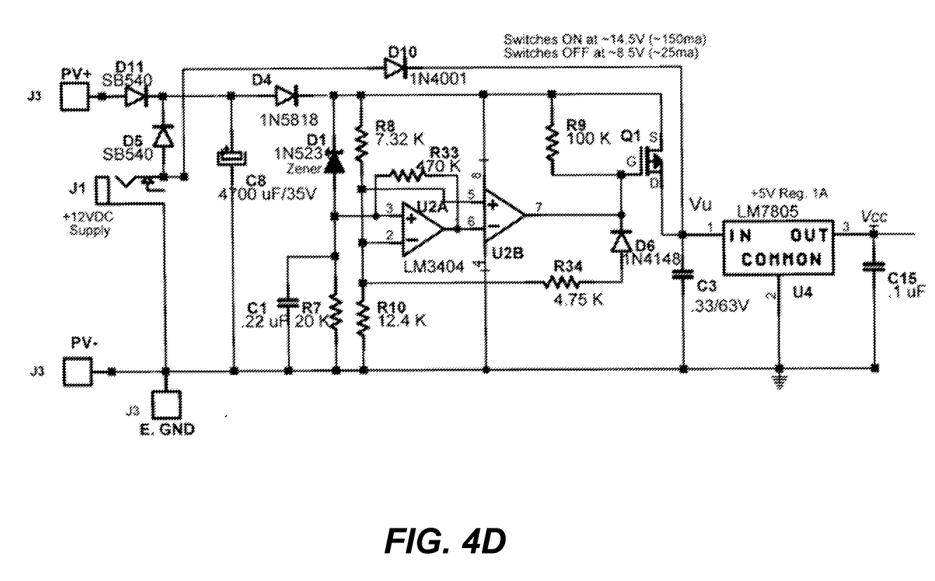

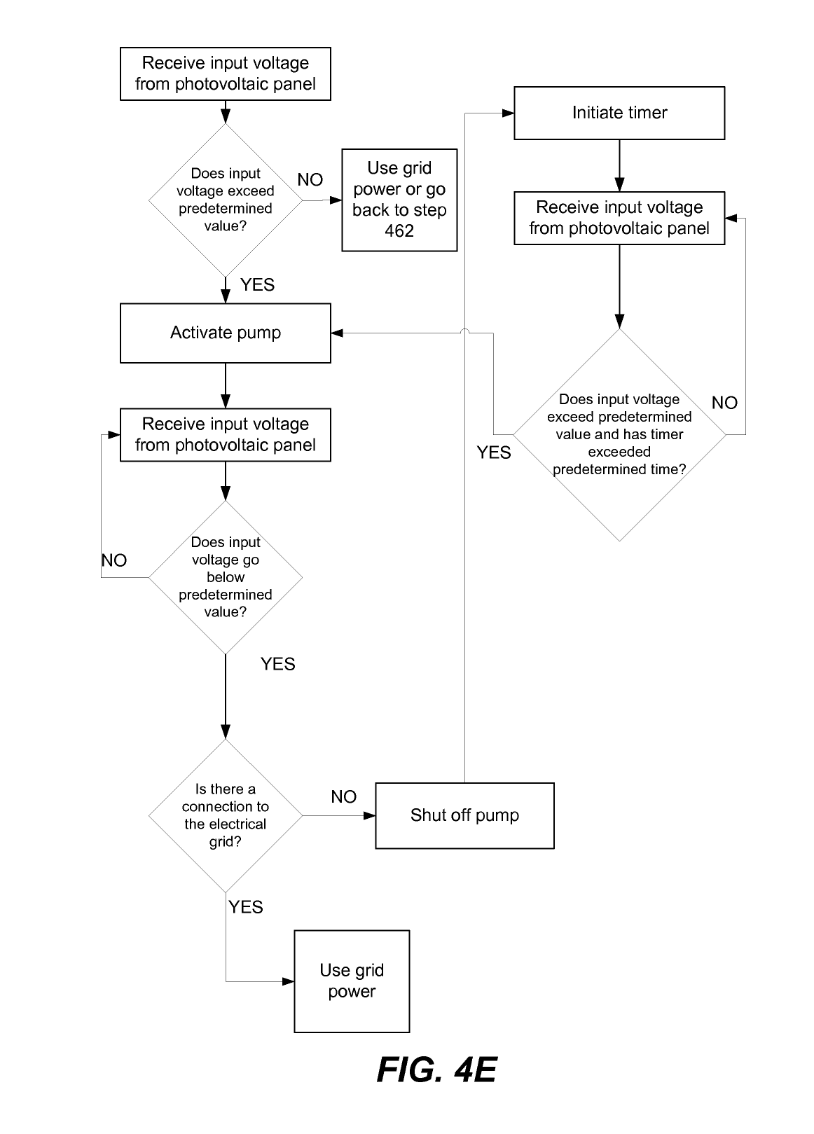

Referring now to FIG. 4A, an arrangement for assessing the functionality of a solar water heating system according to a particular embodiment of the present invention will be described. FIG. 4A is a block diagram that can represent various components of the solar water heating system 100 illustrated in FIG. 1. Controller 122 is coupled with a roof sensor 404, photovoltaic panel 106, one or more pumps 110, water storage tank sensor 405 and a display screen 408. In various implementations, controller 122 includes a processor and/or circuitry for managing voltage input, monitoring temperatures and/or optimizing the overall performance of a solar water heating system.

In various embodiments, controller 122 can include a differential temperature controller. For example, the controller 122 can monitor the temperature difference between water storage tank sensor 405 and the roof sensor 404, which could be coupled with the water storage tank 112 and the solar collector panel 102 of FIG. 1, respectively. If the difference in temperatures measured by the water storage tank sensor 405 and the roof sensor 404 drops below a first amount (e.g., 4° F.), then one or more pumps 110 could be shut off. If the difference in temperature exceeds a second amount (e.g., 10° F.), then the pumps 110 could be turned on.

The differential temperature controller can be used to detect an error in the operating of the solar water heating system and inform a user of the error. A method 420 for such error detection according to one embodiment of the present invention will be described with reference to FIG. 4B. Initially, a temperature difference is calculated between the roof sensor 404 of FIG. 4A and the water storage tank sensor 405 (step 422). The next step involves making a determination as to whether the temperature difference exceeds a predetermined level for a predetermined time (step 424). By way of example, the predetermined level may be between approximately 20° F. and 40° F. and the predetermined time may be between approximately 2 and 6 hours, although other suitable temperatures and durations may be used as well. A predetermined time of between approximately 20 and 240 minutes also works well for various applications. Generally, if the temperatures detected on the roof differ too much for too long from the temperature of the water in the water storage tank, it may indicate that the solar water heating system is failing to adequately heat the water in the water storage tank. In step 426, when it is determined that the temperature difference does exceed the predetermined level for the predetermined time, an error message is sent to the display 408 that is coupled to the controller 122. An owner or user of the solar water heating system, once made aware of the issue, can then investigate the problem or seek technical assistance.

Referring now to FIG. 4C, various components of controller 122 of FIG. 4A according to one embodiment of the present invention will be described. Controller 122 includes a monitoring circuit 450, which is coupled with a photovoltaic panel 106 of FIG. 1. Monitoring circuit 450 is also coupled with voltage regulator module 452, which is in turn coupled with the controller operational circuitry. Pumps 110 are controlled by operational circuitry and a processor. Voltage regulator module 452 receives input voltage from the photovoltaic panel 106 via the monitoring circuit 450 and generates regulated output voltage for powering the controller circuitry. Monitoring circuit 450 helps improve the reliability and performance of the pump circuitry and voltage regulator module 452 by controlling the input voltage received by the voltage regulator module 452.

To understand some of the advantages of this setup, it can be helpful to consider a scenario in which the monitoring circuit 450 did not exist and the photovoltaic panel 106 was directly connected to voltage regulator module 452. A potential problem with this configuration is the volatility of the input voltage provided by the photovoltaic panel 106. For example, at certain times during the day (e.g., the early morning), sunlight is weak or sporadic and the input voltage provided by the photovoltaic panel 106 may be quite small and therefore insufficient to sustain the steady operation of the pumps 110. Such a small input voltage, however, can generate unpredictable behavior by and/or damage the pump circuitry.

To help alleviate this problem, monitoring circuit 450 regulates the input voltage received by the voltage regulator module 452. The monitoring circuit 450 does not switch the input voltage from photovoltaic panel 106 to the voltage regulator module 452 unless the input voltage reaches a minimum voltage amount. The minimum voltage amount can be based on the voltage required to sustain a pump load and maintain the normal operation of the pump circuitry. For example, in one embodiment the minimum switching voltage amount is approximately 14 VDC or greater.

Additionally, monitoring circuit 450 can be configured to prevent the reactivation of the pumps 110 for a period of time following a drop in the input voltage. Assume, for example, that the input voltage from photovoltaic panel 106, after being above a minimum voltage amount for a period of time, suddenly drops below the minimum switching voltage amount. Under such circumstances, the pumps may be shut down based on the above protocol. Immediately thereafter, however, the input voltage may again increase and exceed the minimum voltage amount, causing the pumps to activate. Sporadic ups and downs in the input voltage can cause undesirable short-cycling of the system. To help prevent this problem, monitoring circuit 450 can institute a delay period (e.g., for approximately 2.5 minutes) immediately following such a shutdown. In various implementations, during the delay period, the pumps cannot be activated, irrespective of the input voltage. After the delay period is over, the pumps can be once again activated if the input voltage reaches a minimum switching voltage amount, as described above.

FIG. 4D illustrates a circuit diagram of the controller 122 monitoring circuit 450 and voltage regulator module 452 of FIG. 4C according to one embodiment of the present invention. The circuit consists of a dual single-supply operational amplifier, the LM 3404, denoted U2A and U2B in the schematic, configured as voltage comparators. The output of U2B is used to provide a switching signal to the gate of a P-channel MOSFET, denoted Q1, which switches the input PV voltage ON or OFF to the input of the regulator, denoted U1. As the PV voltage begins to build from zero, the LM 3404 (U2) is energized fully at about 3VDC, and comparators U2A and U2B are biased with the same continuously proportional variable voltage by the voltage divider consisting of R8 and R10. This bias voltage appears at the negative input (pin 2) of U2A and the positive input (pin 5) of U2B. U2A provides a switched input voltage, essentially equivalent to the PV input voltage, to the negative input (pin 6) of U2B. When the output (pin 1) of U2A is low, the output (pin 7) of U2B is high, and the p-channel MOSFET (Q1), therefore, is kept OFF.

As mentioned above, the circuit is designed to prevent activation of the regulator until the input PV voltage is considered to be high enough to provide some load-carrying capability. In the case of this start-up circuit, this has been set to about 14.5VDC, and is defined as the “high threshold”, at which time the control is activated via the regulator. The use of a zener diode (D1) in place of a fixed resistor in the second voltage divider (D1 and R7) that determines the positive input (pin 3) of U2A is the unique means for setting this input to switch the output (pin 1) of U2A high, which in turn switches the output (pin 7) of U2B low, thus switching the MOSFET (Q1) ON and activating the regulator with the PV input voltage of about 14.5VDC. If a fixed resistor was used instead of the zener diode, the proportional input voltages at both the negative and positive inputs of U2A would remain respectively the same; i.e., the positive input (pin 3) would remain at a lower voltage than the negative input (pin 2) as the input voltage increases, and the control would never activate. However, as the voltage across the zener increases and reaches its breakdown threshold, it allows the voltage of the opposing voltage divider at the positive input (pin 3) to rise above that of the negative input (pin 2), and the output of U2A switches to high, thus activating the control circuit as described above. Resistor R23 provides a slight positive feedback to pin 3 for a positive switch without “jitter”. C11 capacitor is provided for filtering any minor transients incoming from the PV input. R8 is provided as a bias (pull-up) to the MOSFET gate to ensure its remaining high until switched by U2B.

After the control is activated as described above, the regulator and control circuit is allowed to operate as long as the input voltage remains above about 8.5VDC, defined as the “low threshold”. This is determined by the network of diode D19 in series with resistor R26, connected from the output (pin 7) of U2B to the negative input (pin 2) of U2A, effectively providing a parallel path to ground, with R10. The effect of this is to somewhat lower the bias voltage at the negative input, so that it will require a greater drop in the input voltage before the voltage at the positive input (pin 3) falls below that of the negative input (pin 2), causing the output of U2A to go low, in turn causing the output of U2B to go high, thus shutting OFF the MOSFET switch and the input voltage to the regulator and control circuit.

A unique feature of the controller 122 illustrated in FIG. 4D is that it can be operated by either grid power, via J1 and D10 as seen in the illustrated embodiment, with the use of a wall mounted 12VDC switching power supply, or the photovoltaic panel 106, or both. This offers a unique measure of power conservation, since the controller 122 and pumps 110 of FIG. 4C draw no power from the grid as long as the voltage output of the photovoltaic panel 106 exceeds 12VDC, as it will do during the stronger portion of the day's solar insulation.

Referring now to FIG. 4E, a method for powering and controlling pumps in a solar water heating system according to a particular embodiment of the invention will be described. More specifically, FIG. 4E is a flow diagram that illustrates steps for drawing power either from a photovoltaic panel 106 of FIG. 4C or the electrical grid to power the pumps 110, depending on the adequacy of the input voltage that is received from the photovoltaic panel 106. It should be appreciated that any of the steps of FIG. 4E may be modified, deleted and/or reordered, depending on the needs of a particular application. It should further be appreciated that some designs do not have all but only a select few of the steps depicted in FIG. 4E.

Initially, input voltage is received from the photovoltaic panel 106 (step 462). A determination is made whether the (open circuit) input voltage from the photovoltaic panel 106 exceeds a predetermined value (step 464). A predetermined value of approximately 12 to 15VDC works well for many applications, although other suitable values are also possible. If the input voltage does not exceed the predetermined value, step 462 may be repeated. If access to the electrical grid is available (e.g., through the power supply 124 of FIG. 1, which in some implementations involves a pluggable 12VDC power supply, a standard power outlet, etc.) the pumps may be powered by the electrical grid instead of the photovoltaic panel 106 (step 465).

If the input voltage does exceed the predetermined value, the pumps may be activated using power drawn from the photovoltaic panel 106 (step 466). Afterward, input voltage from the photovoltaic panel 106 will be monitored (step 467) to see if it drops below a predetermined value (step 468). By way of example, the predetermined value may be between approximately 5 and 10VDC. If the input voltage does not drop below the predetermined value, the monitoring will continue and step 467 will be repeated. If the input voltage does go below the predetermined value, the next step may depend on whether or not access to the electrical grid is available (step 472). If that is the case, the pumps 110 may be activated using grid power (step 473).

If access to the electrical grid is unavailable or undesirable, the pumps 110 will be shut off (step 474). A timer will begin (step 476). The input voltage from the photovoltaic will again be monitored (step 478). If the input voltage exceeds a predetermined value (e.g., approximately between 12 and 15VDC) and the timer indicates that a predetermined amount of time has passed (step 480), the pumps are reactivated (step 466). The predetermined amount of time may vary, although an amount between 2 and 5 minutes seems to work well for various applications. As noted earlier, the use of the timer helps prevent the short-cycling of the pumps. If the conditions of step 480 are not met, then the input voltage from the photovoltaic panel will continue to be monitored (step 478) until they are.

It should be noted that in some implementations, after a switch to grid power has been made (e.g., at steps 465 or 473), the input voltage from the photovoltaic panel 110 may be continuously monitored. When the input voltage meets the right criteria (e.g., the criteria of steps 464 and/or step 480), the pumps 110 will instead be powered by the photovoltaic panel 110, rather then the electrical grid. As a result, various designs allow for the pumps 110 of the solar water heating system to switch as appropriate from solar to grid power and back again, depending on the availability of sunlight. Such an approach can help minimize the use of grid power while also helping to ensure that the pumps are available when needed.

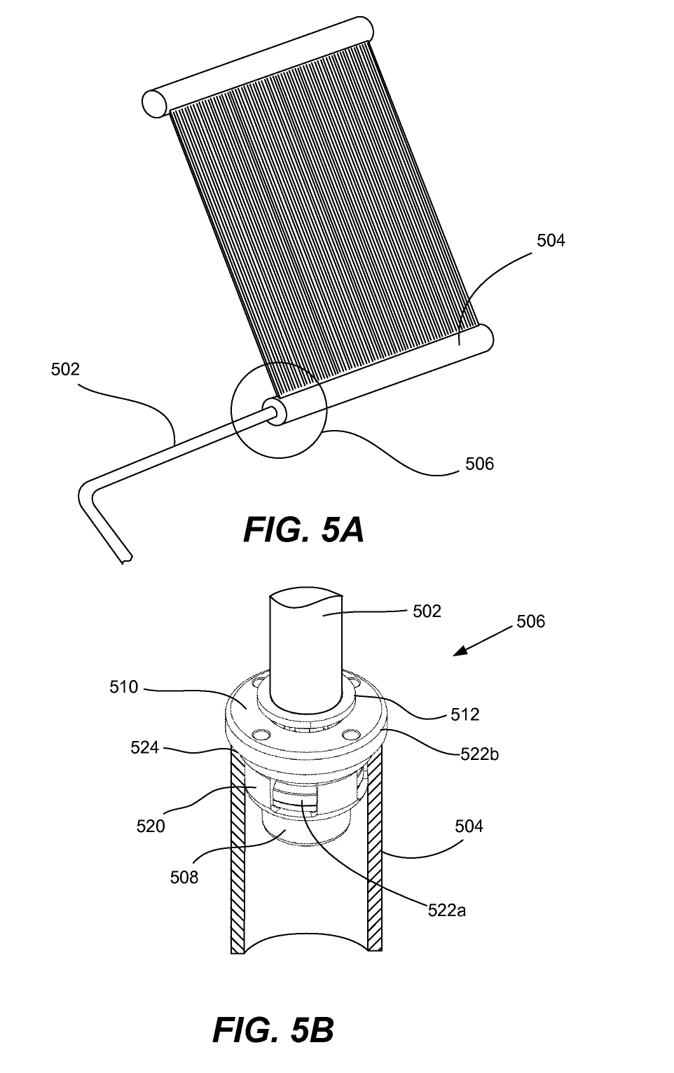

Referring now to FIG. 5A, a header insert assembly for securely coupling a pipe to a header of a solar collector panel according to a particular embodiment of the present invention will be described. FIG. 5A provides an enlarged view of the solar collector panel 102 of FIG. 1. A header insert assembly 506 is positioned at the end of the header 504. A pipe 502 is inserted into the header insert assembly 506 and is fluidly connected to the header 504 of the solar collector panel 102. In various embodiments, the header insert assembly 506 enables the pipe 502 to be readily attached to the header 504 without use of tools or welding. This can help simplify and accelerate the assembly of the solar water heating system 102.

An embodiment of the header insert assembly 506 is illustrated in greater detail in FIGS. 5B and 5C. FIG. 5B illustrates how the header insert assembly 506 can couple a header 504 to a pipe 502. FIG. 5C illustrates various components of the header insert assembly 506. The header insert assembly 506 includes a header insert 508, an o-ring 514, an o-ring guide 516, a body 510, a collet 512 and a collet lock 514. (It should be noted that the figures are diagrammatic and are not necessarily to scale. The collet lock 514 illustrated in FIG. 5C, in particular, has been magnified for clarity and is typically sized to fit around the collet 512.)

As is well recognized by persons of ordinary skill in the art, collets and o-rings are known for connecting pipes. However, to the best knowledge of the inventors, they have not been used to form a push fitting for a header in a solar water heating system, nor have they been made part of a header insert assembly 506 as described herein. It should be appreciated that components of the header insert assembly 506, such as the header insert 508, the body 510 and the collet lock 514, offer advantages not found in conventional solar water heating systems. Generally, the components are easy to assembly, facilitate rapid connecting of the solar collector panel to a piping system with little or no use of tools and welding, help ensure strong, watertight seals between an inserted pipe and the header, and can help protect an off-the-shelf component (e.g., a collet) from sustained exposure to ultraviolet rays.

The header insert 508 is arranged to be easily secured to the end of the header 504 without the use of welding or tools. The header insert 508 includes an aperture 518 that is encircled by a collar 520. The aperture 518 leads to a fluid passage within the header 504. The collar 520 is arranged to press tightly against the inside of the header 504. In the illustrated embodiment, the collar 520 is made of multiple tabs that extend perpendicular to the aperture 518, although a wide variety of collar designs may be used. In various embodiments, the header insert 508 snaps easily and firmly into place after being pushed into an end of the header 504.

The o-ring 514 and o-ring guide 516 are positioned over the header insert 508. The o-ring 514 helps form a watertight seal with a pipe 502 that is inserted into the header insert assembly 506. The o-ring guide 516 is also positioned over the header insert 508 and helps align the o-ring 514 with the pipe 502. The header insert 508 is arranged to help prevent the o-ring 514 and the o-ring guide 516 from falling backward into the header 504.

The body 510 includes an inner portion 522a that is disposed within the header 504 and an outer portion 522b that extends outside of the header 504. The inner portion 522a fits into the collar 520 of the header insert 508. In various implementations, the collar 520 clamps down on and/or or latches onto the inner portion 522a of the body 510. The outer portion 522b has a larger cross-sectional circumference than the inner portion 522a and overlies an outer surface 524 of the header 504. In various embodiments, the body 510 is spin welded to the header 504 and other components of the header insert assembly 506. The friction of the spin welding process can weld the outer surface 524 of the header 504 to the outer portion 522b of the body 510, which helps strengthen the bond between the header insert assembly 506 and the header 504. Some designs contemplate one or more holes 526 on a top surface 528 of the body 510 that are arranged to receive a spin welding device or another suitable assembly tool. The top surface 528 of the body 510 also includes an aperture 530, which leads to a fluid passage that penetrates entirely through the inner and outer portions of the body 510 and ultimately connects to the fluid passage inside the header.

The collet 512 is inserted into the aperture 530 on the body 510 and is arranged to slide in and out of the body 510. The collet 512 also includes one or more teeth 532. The teeth 532 are arranged to hold a pipe 502 that is inserted into the collet 512 and the header insert assembly 506. More specifically, when the collet is slid into a first position where more of the collect is inserted into the body 510, the teeth 532 pull away from the pipe 502. When the collect is slid into a second position where less of the collet is inserted into the body 510, the teeth 532 clap down on the pipe 502 and help hold it firmly in place. In some embodiments, the teeth are made of stainless steel or another suitable metal.

To help secure the pipe 502 and protect the collet, a collet lock 514 is used. In various embodiments, the collet lock 514 is made of a UV-resistant polymer and is arranged to snap onto and cover the collet 512 so that none of the collet 512 is exposed. Therefore, the collet 512 is shielded from ultraviolet radiation. In addition, when the collet lock 512 is latched over the collet 512, the collet lock 512 maintains the collet 512 in the aforementioned second position. That is, it helps to prevent the collet 512 from sliding deeper into the body 510. As a result, the teeth 532 of the collet 512 are fastened securely to the pipe 502 that is inserted into the collet 512. The collet lock 514 can be structured in a wide variety of ways, depending on the needs of a particular application. In the illustrated embodiment, for example, the collet lock 514 is in an open position in which two half-circle-like components 535 are connected together by a hinge 534. The collet lock 514 can be placed in a closed position by swiveling the components around the hinge 534 and bringing them together to form a circle-like lock. When locked around the cylindrical collet 512, the collet lock 514 serves to both protect the collet 512 and secure the pipe 502 to the header 504.

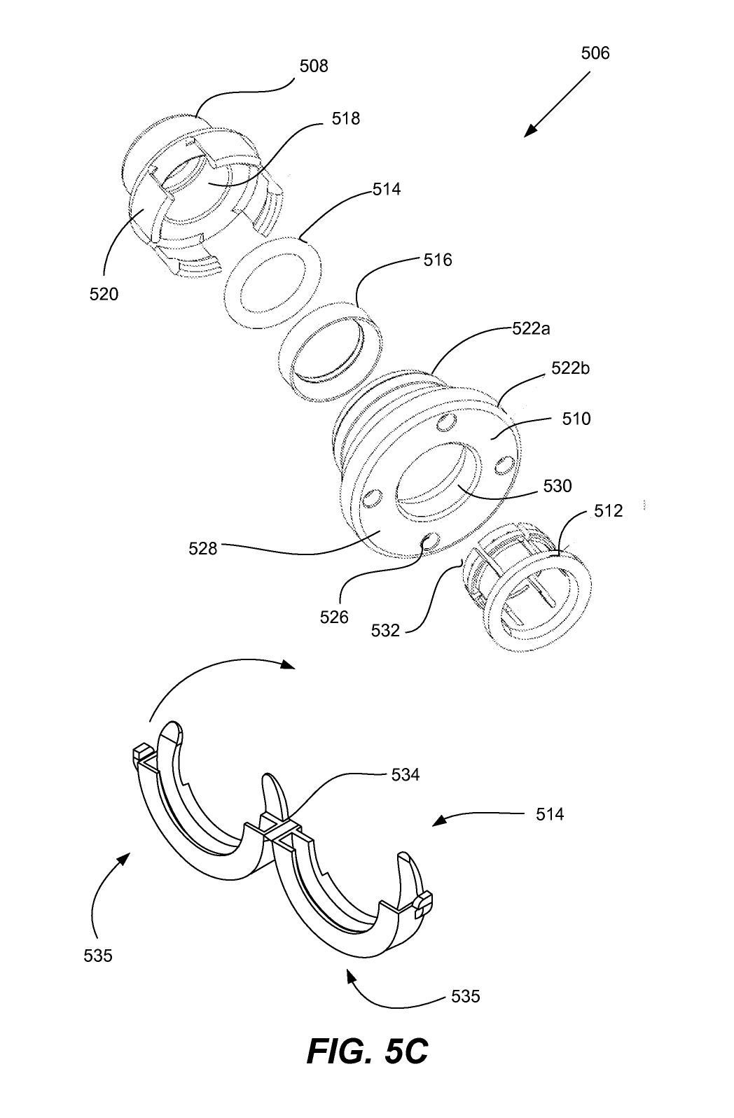

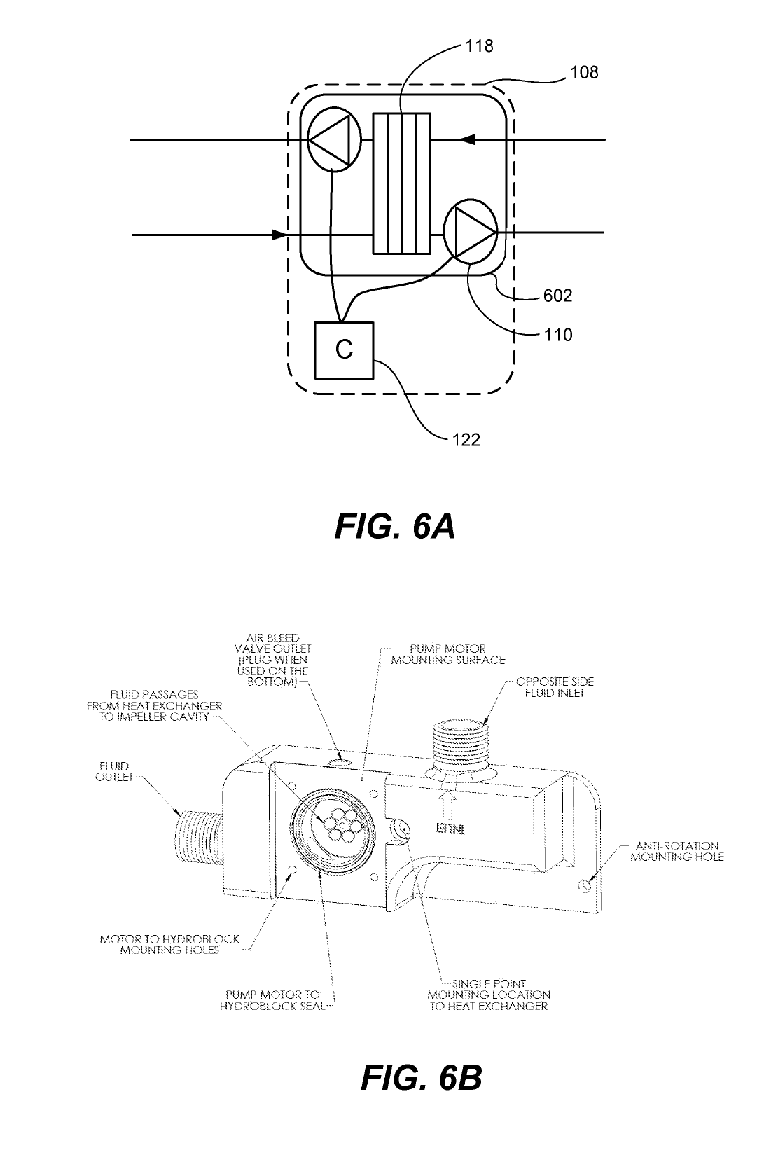

Referring now to FIG. 6A, the interface module 108 of FIG. 1 according to one embodiment of the present invention will be described. Some designs involve an interface module 108 that integrates multiple control, pumping and monitoring functions into one device. In the illustrated embodiment, for example, the interface module 108 includes pumps 110, heat exchanger 118 and/or one or more hydroblocks 602. The interface module 108 may further include a controller 122, insulation and filtration components.

Hydroblock 602 is an integrated module that interfaces with a fluid loop (e.g., first and/or second fluid loops 130 and 132 of FIG. 1), one or more pumps 110 and a heat exchanger 118 to help perform any of the operations (e.g., heat exchange, pumping, etc.) discussed in connection with the preceding figures. Additionally, the hydroblock 602 can perform other functions, such as air venting, valving and filtration, and may not require additional fittings, tubing, soldering and/or connectors to be securely coupled with the aforementioned components. In some implementations, each hydroblock 602, for example, is formed from a single molding process. By integrating various functions and interfaces into a single unit, the hydroblock 114 can help simplify assembly, reduce part count and lower costs. One example of a hydroblock 602 is illustrated in FIG. 6B. In FIG. 6B, the hydroblock 602 is arranged with one fluid inlet and one fluid outlet, and thus can be coupled with only one loop (e.g., first fluid loop 130 or second fluid loop 132) of FIG. 1. In various embodiments, an integrated hydroblock includes at least two inlet and two outlet ports and can interface with multiple such loops in a solar water heating system.

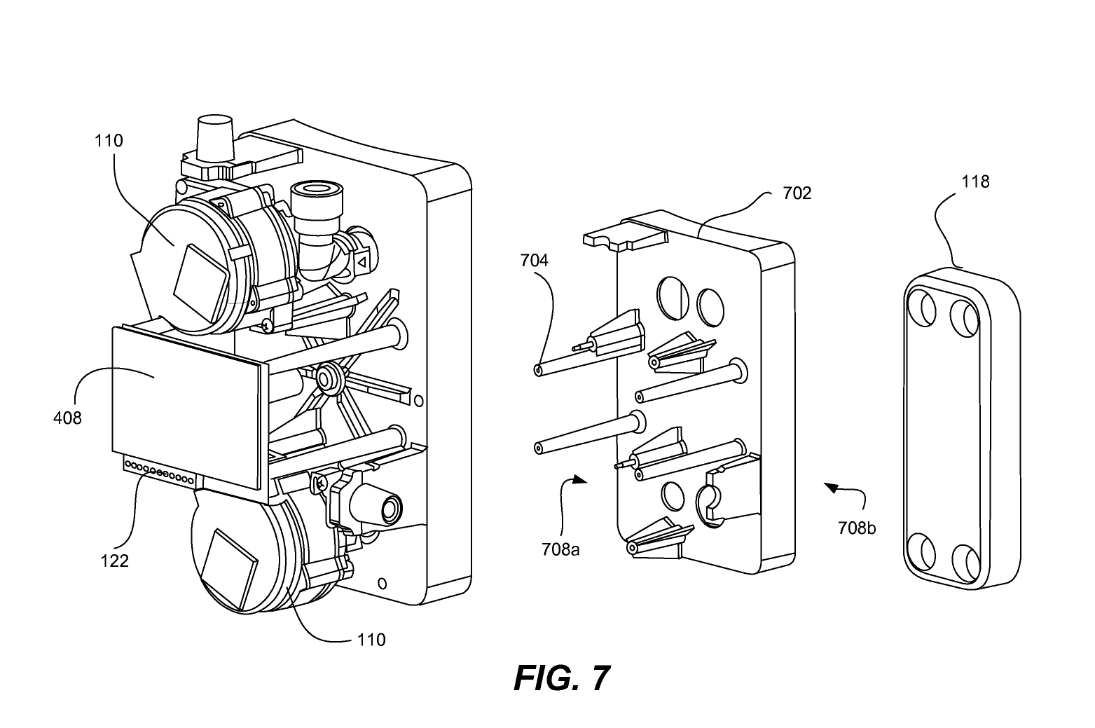

Referring next to FIG. 7, an interface module 700 according to another embodiment of the present invention will be described. The interface module 700 is arranged to combine multiple solar water heating components and operations (e.g., pumping, control mechanisms, heat transfer, error messaging, etc.) into a single, compact unit. In various embodiments of the present invention, the integrated circuit module 108 is arranged to fit within a rectangular prism measuring no larger than 10″×7″×6″.

The interface module 700 includes a base 702, a heat exchanger 118, pumps 110, a controller 122, and a display 408. In various embodiments, the base 702 is integrally formed from a single piece of plastic and/or using a single molding process. The heat exchanger 118 is coupled to the back side 708b of the base 702. The controller 122, the display 408 and the pumps 110 are mounted on the opposing front side 708a. One or more pedestals 704 extend perpendicular to and out of the front side 708b of the base 702. The support structures support the controller 122 and the display 408. In some designs, a plastic housing (not shown) encases the interface module 700.

The controller 122 can be arranged to include any of the circuitry and perform any of the operations described in connection with FIGS. 4A-4E. The controller 122 may include memory, a processor and/or circuitry for electrically coupling the controller 122 to the pumps 110, the display 408, a roof sensor, a water storage sensor and other suitable components of a solar water heating system. In various embodiments, the display 408 may be arranged to display text and/or images and may include an LCD screen, one or more lights or light-emitting diodes, etc.

Although only a few embodiments of the invention have been described in detail, it should be appreciated that the invention may be implemented in many other forms without departing from the spirit or scope of the invention. In the foregoing description, for example, a component of one figure may be used to modify a corresponding component in another figure. For example, FIGS. 6A and 7 refer to interface modules, each of which may replace or be used to modify the interface module 108 of FIG. 1. It should also be appreciated that although any one component may be described in the specification as including multiple features, the present invention also contemplates a corresponding component that include only one or more of those features. For example, the solar water heating system 100 of FIG. 1 is depicted as including a photovoltaic panel, push fittings, an expansion reservoir, an unglazed, polymer solar collector panel, etc. It should be noted that the present invention also contemplates almost any subset or combination of the depicted features (e.g., a solar water heating system with an expansion reservoir and a glazed solar collector panel that lacks a photovoltaic panel and push fittings, etc.) In another example, the expanded reservoir 104 of FIG. 2B is described and shown as having a pressure release valve, a deformable bladder and a fluid passage. However, in another embodiment the expanded reservoir 104 may lack a pressure release valve that is directly coupled to the reservoir 104 as shown in FIG. 2B. For example, the pressure release valve may be instead directly coupled to an intermediate part or pipe that is itself coupled with the expanded reservoir 104. With respect to the method illustrated in FIG. 4E, it should be further noted that the various steps need not always be combined together as shown in the figure. For example, an implementation is also contemplated that only involves steps 462, 464 and 466, and that involves none or only some of the other steps described therein. It should also be noted that in some approaches, various steps may be reordered and/or may occur substantially simultaneously. Therefore, the present embodiments should be considered as illustrative and not restrictive and the invention is not limited to the details given herein, but may be modified within the scope and equivalents of the appended claims.

What is claimed is:

1. A solar water heating system comprising:
a solar collector panel;
a solar water heating component;
a piping system;
an expansion reservoir comprising:
a fluid passage having a fluid inlet and a fluid outlet that are both fluidly coupled with the solar collector panel and the solar water heating component via the piping system;
a deformable bladder that is disposed adjacent to the fluid passage and that includes at least one aperture, wherein the deformable bladder is arranged to regulate its internal pressure such that air is expelled out of the at least one aperture from the deformable bladder when pressure in the fluid passage increases and air is drawn into the deformable bladder through the at least one aperture when contraction of fluid in the fluid passage forms a vacuum in the expansion reservoir; and
a housing that encases the fluid passage and the deformable bladder.

2. A solar water heating system as recited in claim 1, further comprising a pressure release valve that is coupled to the fluid passage and is arranged to release vapor from the fluid passage when the pressure within the fluid passages reaches a predetermined maximum pressure level.

3. A solar water heating system as recited in claim 2, wherein the predetermined maximum pressure level is at least one selected from a group consisting of: 1) less than approximately 10 psi; and 2) approximately between 0.25 and 2 psi.

4. A solar water heating system as recited in claim 1, wherein the housing is made of a UV-resistant polymer.

5. A solar water heating system as recited in claim 1, wherein the deformable bladder is arranged to be entirely compressed and deflated when the fluid passage is entirely filled with fluid.

6. A solar water heating system as recited in claim 1, wherein the solar water heating component is an interface module with a heat exchanger.

7. A solar water heating system as recited in claim 1, wherein the deformable bladder is arranged to self-regulate its internal pressure such that its internal pressure is substantially equal to the pressure in the ambient environment.

8. A solar water heating system as recited in claim 1, wherein the solar collector panel is unglazed.

9. A solar water heating system as recited in claim 1, wherein the solar collector panel and the expansion tank are mounted adjacent to one another on a roof of a building.

10. A solar water heating system as recited in claim 1, wherein the at least one aperture involves at least one of a group consisting of: 1) at least one valve that includes the at least one aperture; 2) a first aperture for releasing air and a second aperture for drawing in air; 3) being constantly open to the ambient environment; and 4) being selectively open and closed to the ambient environment.

11. A solar water heating system as recited in claim 1, further comprising:
a photovoltaic panel that is electrically coupled to the interface module;
an electrical connection to an external electrical grid, wherein the interface module and the one or more pumps are arranged to selectively receive electricity from both the photovoltaic panel and the external electrical grid.

12. A solar water heating system as recited in claim 1, wherein the solar collector panel further comprises:
an absorber;
a pair of headers, the headers being positioned at opposite ends of and in fluid communication with the absorber, a first header being disposed at a top end of the absorber, a second header being disposed at a bottom end of the absorber; and
a header insert assembly attached to an end of each header, wherein the header insert assembly allows a tube to be readily secured to the header to form a watertight seal without use of tools and without welding.

13. A solar water heating system as recited in claim 1, wherein each header insert assembly is attached to an associated header of the solar collector panel, each header insert assembly further comprising:
a header insert that includes an aperture and a collar that extends around the periphery of the aperture, the aperture of the header insert leading to a fluid passage within the header, the header insert inserted into the header and arranged to press tightly against the inside of the header to hold the header insert in place, wherein the header insert is arranged to be readily attached to the inside of the header without welding;
an o-ring positioned over the header insert and arranged to help form a watertight seal with a tube that is inserted into the header insert and the header, wherein the header insert is arranged to help prevent the o-ring from falling back into the header;
a body that includes an inner portion and an outer portion, the collar on the header insert arranged to clamp onto the inner portion of the body, the outer portion of the body having a larger circumference than the inner portion and protruding outside of the header, wherein the body is spin welded to the header such that the outer portion of the body is welded to the exterior of the header; and
a collet that is inserted into the body, the collet including a plurality of teeth and being arranged to slide from a first position in which more of the collet is inserted into the body to a second position where less of the collet is inserted into the body, wherein the collet is arranged such that the teeth clamp down on a tube when the tube is pushed into the header insert assembly and the collet is in the first position and wherein the collet is further arranged such that the teeth pull away from the tube when the tube is inserted into the header insert assembly and the collar is in the second position; and
a removable collet lock that latches onto the collet to prevent the collet from sliding from the second position into the first position, wherein the collet lock is made of a UV-resistant polymer to help protect the collet from UV radiation.

14. A solar water heating system as recited in claim 1, wherein the interface module further comprises a hydroblock that is integrally formed from a polymer using a single molding process, the hydroblock including:
a first conduit with a first fluid inlet and a first fluid outlet that are in fluid communication with the first fluid loop connecting the interface module with the solar collector panel;
a second conduit with a second fluid inlet and a second fluid outlet that are in fluid communication with the second fluid loop connecting the interface module with the external water storage tank, the first and second conduits not being in fluid communication; and
an interface that is attached to the heat exchanger and one or more pumps, wherein the hydroblock is arranged to help circulate fluids through the first fluid loop and the second fluid loop using the one or more pumps and to transfer heat from the first fluid loop to the second fluid loop using the heat exchanger.

15. A solar water heating system as recited in claim 14, wherein the interface module integrates the heat exchanger, the hydroblock and the one or more pumps into a single device that fits within a rectangular prism that is approximately 10 inches×7 inches×6 inches.

16. A system for back flushing a filter in a solar water heating system, the system comprising:
a water storage tank;
a solar water heating component;
a piping system that fluidly couples the solar water heating component, the water storage tank and an external water source;
a pipe adapter that is coupled to the piping system, the pipe adapter including first, second and third openings that provide access to first, second and third fluid conduit passages within the pipe adapter, the first, second and third fluid conduit passages being fluidly connected at an intersection point within the pipe adapter, wherein the first and second openings of the pipe adapter are fluidly coupled with the water storage tank and the solar water heating component respectively and wherein the third opening is arranged to be coupled with the water source; and
a filter that is positioned at the intersection point of the pipe adapter, wherein:
the filter is arranged to filter and trap debris from the water storage tank when water is passed from the water storage tank to the solar water heating component through the first opening, the first conduit passage, the second conduit passage and the second opening of the pipe adapter; and
the filter is arranged such that water cleans away the debris from the filter when water is passed from the water source to the water storage tank through the third opening, the third fluid conduit passage, the first conduit passage and the first opening of the pipe adapter.

17. A system as recited in claim 16, wherein the solar water heating component is an interface module having a heat exchanger and the water source is an external water main.

18. A system as recited in claim 16, wherein the filter is a hollow, cylindrical structure that includes a rubber end attached to a metal wire mesh, the rubber end forming a water tight seal with the inside of the second fluid conduit passage, the wire mesh being positioned directly between the first and third fluid conduit passages.

19. A system as recited in claim 16, wherein the system is arranged such that water travels in a first direction through the filter when water is passed from the water storage tank to the solar water heating component and water travels through the filter in a second direction opposite the first direction when water is passed from the water source to the water storage tank.

20. A system as recited in claim 16, wherein the solar water heating component is an interface module that includes a pump, the pump being arranged to pull water from the water storage tank towards the solar water heating component such that, during the pumping of water between the water storage tank and the solar water heating component, the majority of the pulled water is directed from the first fluid conduit passage of the pipe adapter to the second fluid conduit passage and not the third fluid conduit passage.

21. A system as recited in claim 16, wherein the pipe adapter is a t-joint.

22. A method of regulating electrical power in a solar water heating system, the method comprising:
receiving a first input voltage from a photovoltaic panel that is electrically coupled with a pump in an interface module of a solar water heating system, wherein the interface module also includes a heat exchanger and is coupled with a water storage tank and a solar collector panel via a piping system;
determining whether the first input voltage exceeds a predetermined first voltage; and
when it is determined that the first input voltage exceeds the predetermined first voltage, routing the first input voltage to the pump to activate the pump.

23. A method as recited in claim 22, further comprising:
while the pump is activated, receiving a second input voltage from the photovoltaic panel;
determining whether the second input voltage is below a predetermined second voltage; and
when it is determined that the second input voltage is below the predetermined second voltage, shutting off the activated pump;

24. A method as recited in claim 22, further comprising:
after the shutting off of the activated pump, initiating a timer; and
when it is determined that the timer exceeds a predetermined period of time and the first input voltage exceeds the predetermined first voltage, reactivating the shut off pump.

25. A method as recited in claim 22, wherein:
the interface module and the pump are electrically connected to an external electrical grid via a power supply;
while the pump is activated, receiving a second input voltage from the photovoltaic panel;
determining whether the second input voltage from the photovoltaic panel is below a predetermined second voltage; and
when it is determined that the second input voltage from the photovoltaic panel is below the predetermined second voltage, preventing electrical power from being drawn from the photovoltaic panel and routing electrical current from the electrical grid to power the pump.

26. A method as recited in claim 22, further comprising:
calculating a temperature difference between a first temperature that is based on a roof sensor positioned near the solar collector panel and a second temperature based on a sensor in the water storage tank;
determining whether the temperature difference exceeds a predetermined level for a predetermined period of time; and
when it is determined that the temperature difference exceeds the predetermined level for the predetermined period of time, displaying an error message on a display screen that is mounted on the interface module.
